(19) United States
(12) Patent Application Publication
(10) Pub. No.: US 2022/0322564 A1
(43) Pub. Date: Oct. 6, 2022

(54) COOLING DEVICE

(71) Applicant: FUJITSU LIMITED, Kawasaki-shi (JP)

(72) Inventors: Hideo KUBO, Kawasaki (JP); Kenji SASABE, Kawasaki (JP); Shinnosuke FUJIWARA, Kawasaki (JP); Nobumitsu AOKI, Kawasaki (JP); Keita HIRAI, Kawasaki (JP); Atsushi ENDO, Kawasaki (JP); Masahide KODAMA, Kawasaki (JP); Kento OHGA, Yokohama (JP)

(73) Assignee: FUJITSU LIMITED, Kawasaki-shi (JP)

(21) Appl. No.: 17/567,928

(22) Filed: Jan. 4, 2022

(30) Foreign Application Priority Data
Apr. 6, 2021 (JP) 2021-064925

(51) Int. Cl. H05K 7/20

(52) U.S. Cl. CPC H05K 7/2039; H05K 7/20309; H05K 7/20318

(57) ABSTRACT

A cooling device includes: a downstream heat radiation member that includes a plurality of downstream fins; and an upstream heat radiation member that is arranged on an upstream side in a flow direction of cooling air with a gap from the downstream heat radiation member, includes a plurality of upstream fins, and is provided with a low pressure loss portion in which pressure loss is lower than pressure loss in another portion in one portion in a fin arrangement direction orthogonal to the flow direction.

### CROSS-REFERENCE TO RELATED APPLICATION

This application is based upon and claims the benefit of priority of the prior Japanese Patent Application No. 2021-64925, filed on Apr. 6, 2021, the entire contents of which are incorporated herein by reference.

### FIELD

The embodiments discussed herein are related to a cooling device.

### BACKGROUND

There is a heat sink in which heat radiation fins of the same size are arranged on a base plate of the heat sink at different densities and at predetermined intervals in a direction of wind. In this heat sink, the heat radiation fins are arranged such that arrangement density of fins on a windward side is smaller than arrangement density of fins on a leeward side.

Japanese Laid-open Patent Publication No. 2003-28831 and Japanese Laid-open Patent Publication No. 9-64568 are disclosed as related art.

### SUMMARY

According to an aspect of the embodiments, a cooling device includes: a downstream heat radiation member that includes a plurality of downstream fins; and an upstream heat radiation member that is arranged on an upstream side in a flow direction of cooling air with a gap from the downstream heat radiation member, includes a plurality of upstream fins, and is provided with a low pressure loss portion in which pressure loss is lower than pressure loss in another portion in one portion in a fin arrangement direction orthogonal to the flow direction.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a perspective view illustrating a cooling device of a first embodiment;

FIG. 2 is an exploded perspective view illustrating the cooling device of the first embodiment;

FIG. 3 is a partial plan view illustrating an electronic device including the cooling device of the first embodiment together with an internal structure of the cooling device;

FIG. 4 is a plan view illustrating the internal structure of the cooling device of the first embodiment;

FIG. 5 is a cross-sectional view taken along a line 5-5 of FIG. 4, illustrating the cooling device of the first embodiment in a non-inclined state;

FIG. 6 is a cross-sectional view illustrating the cooling device of the first embodiment in an inclined state;

FIG. 7 is a plan view illustrating one end portions of transport pipes in the cooling device of the first embodiment together with a part of an evaporation unit;

FIG. 8 is a cross-sectional view illustrating another end portion of the transport pipe in the cooling device of the first embodiment together with a part of a container;

FIG. 9 is a side view illustrating the one end portion of the transport pipe in the cooling device of the first embodiment together with a part of the evaporation unit;

FIG. 10 is a graph indicating a relationship between an inner diameter of the transport pipe and a height of a water column rising in the transport pipe;

FIG. 11 is a cross-sectional view illustrating a state where a refrigerant evaporates in the cooling device of the first embodiment;

FIG. 12 is a cross-sectional view illustrating a state where the refrigerant condenses in the cooling device of the first embodiment;

FIG. 13 is a cross-sectional view taken along a line 13-13 of FIG. 4, illustrating the cooling device of the first embodiment;

FIG. 14 is a plan view illustrating an upstream heat radiation member and a downstream heat radiation member of the cooling device of the first embodiment;

FIG. 15 is a plan view illustrating the upstream heat radiation member and the downstream heat radiation member of the cooling device of the first embodiment together with an air flow;

FIG. 16 is a plan view illustrating the internal structure of the cooling device of the present disclosure together with an injection hole and an injection pipe;

FIG. 17 is a cross-sectional view taken along a line 17-17 of FIG. 16, illustrating the internal structure of the cooling device of the present disclosure;

FIG. 18 is a cross-sectional view illustrating the injection pipe of the cooling device of the present disclosure in an unsealed state;

FIG. 19 is a cross-sectional view illustrating the injection pipe of the cooling device of the present disclosure in a compressed and sealed state;

FIG. 20 is a cross-sectional view illustrating the injection hole of the cooling device of the present disclosure in a state of being sealed with a plug at a tip of the injection pipe;

FIG. 21 is a graph indicating a relationship between a wind speed of cooling air and thermal resistance of a fin;

FIG. 22 is a graph indicating a relationship between pressure loss and the thermal resistance of the fin;

FIG. 23 is a plan view illustrating a cooling device of a second embodiment;

FIG. 24 is a side view illustrating an electronic device including the cooling device of the second embodiment;

FIG. 25 is a plan view illustrating the cooling device of the second embodiment together with an air flow;

FIG. 26 is a plan view illustrating a cooling device of a third embodiment;

FIG. 27 is a plan view illustrating a cooling device of a fourth embodiment;

FIG. 28 is a plan view illustrating a cooling device of a fifth embodiment;

FIG. 29 is a plan view illustrating a cooling device of a sixth embodiment;

FIG. 30 is a cross-sectional view taken along a line 30-30 of FIG. 29, illustrating the cooling device of the sixth embodiment together with an electronic device;

FIG. 31 is a perspective view illustrating a structure of the fins in the disclosed technology as a first modification;

FIG. 32 is a perspective view illustrating the structure of the fins in the disclosed technology as a second modification;

FIG. 33 is a perspective view partially illustrating a third modification of the cooling device of the disclosed technology;

FIG. 34 is a cross-sectional view partially illustrating a fourth modification of the cooling device of the disclosed technology; and

FIG. 35 is a cross-sectional view partially illustrating the fourth modification of the cooling device of the disclosed technology.

### DESCRIPTION OF EMBODIMENTS

Furthermore, there is a radiator including a heat radiation unit in which a large number of plate-shaped fins are arranged such that plate surfaces thereof are parallel to a flow path of an air flow generated by an axial flow fan. In this radiator, the fin group is formed such that fin intervals are coarse at a central portion of the heat radiation unit and the fin intervals are dense at both side portions of the heat radiation unit.

In a cooling device that cools an object to be cooled by radiating heat of the object to be cooled with a plurality of fins, it is conceivable to improve cooling efficiency by, for example, partially increasing arrangement density of the fins.

However, only by partially increasing the arrangement density of the fins, the improvement of the cooling efficiency is limited in a case where mounting density of various electronic components such as the object to be cooled is high, for example. For example, in the cooling device that cools the object to be cooled by radiating heat of the object to be cooled with the plurality of fins, there is room for improvement in terms of improving the cooling efficiency.

As one aspect, the disclosed technology of the present application aims to improve cooling efficiency in a cooling device that cools an object to be cooled by radiating heat of the object to be cooled with a plurality of fins.

A cooling device 42 of a first embodiment will be described in detail with reference to the drawings.

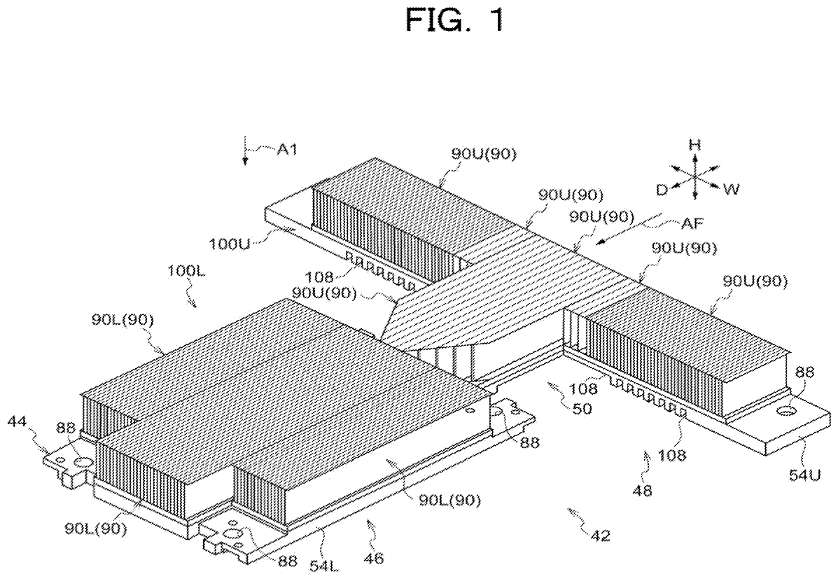

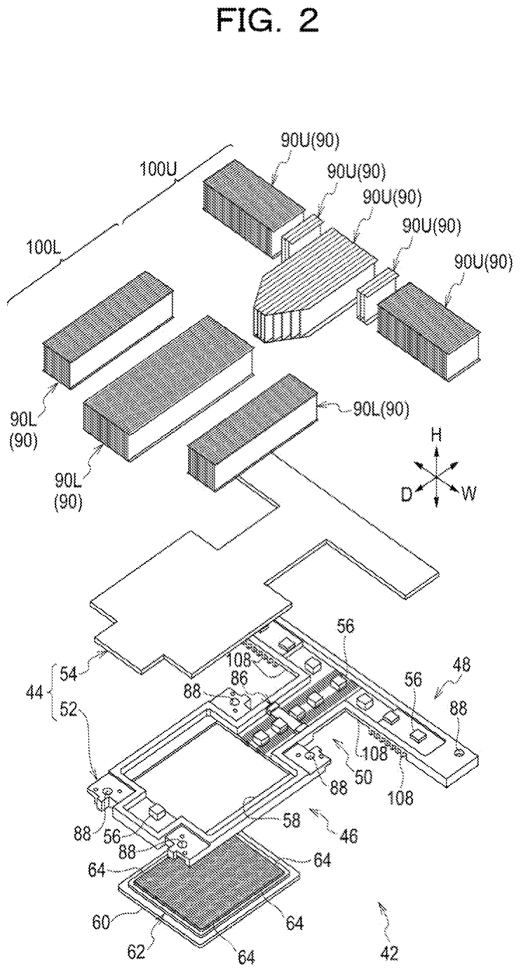

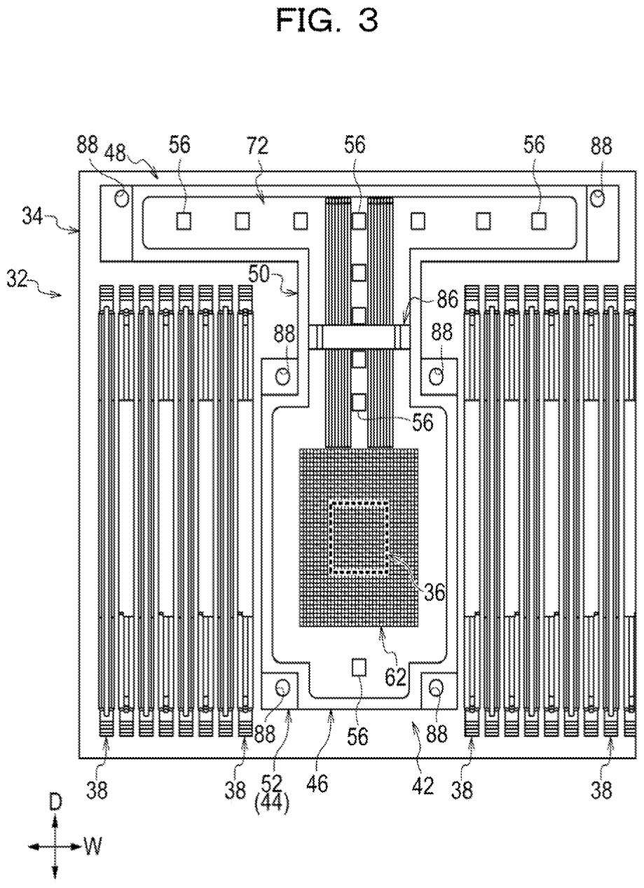

FIGS. 1 and 2 illustrate the cooling device 42 of the first embodiment. Furthermore, FIG. 3 illustrates an electronic device 32 including the cooling device 42. Examples of the electronic device 32 include, but are not limited to, an information communication device such as a server.

The electronic device 32 includes a substrate 34 having rigidity and an insulation property. A plurality of elements 36 and 38 is mounted on the substrate 34. The types of the elements 36 and 38 are not particularly limited, but in the example illustrated in FIG. 3, the element 36 is a processor chip and the elements 38 are memory modules. In this case, the element 36 is an example of a heating element. In addition, in order to cool the element 36, the cooling device 42 is arranged in contact with the element 36.

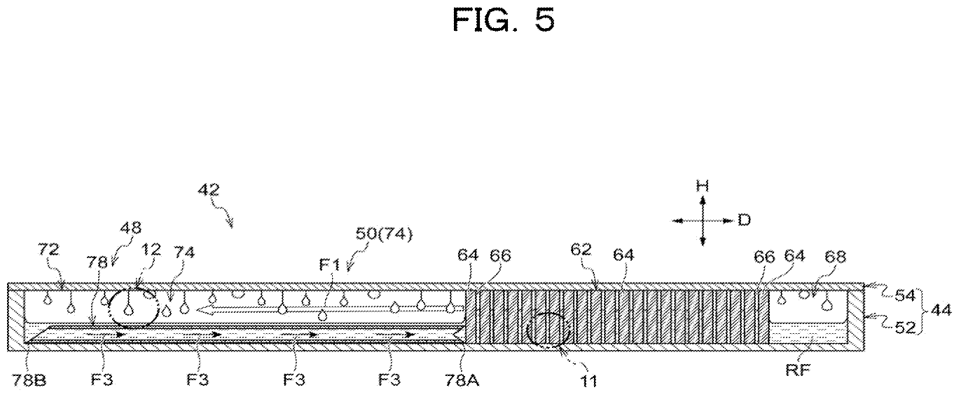

As illustrated in FIGS. 1 to 5, the cooling device 42 includes a container 44. In the container 44, a refrigerant RF (see FIG. 5) is sealed. In addition, the cooling device 42 includes a heat reception unit 46, a heat radiation unit 48, and a connection unit 50. In the first embodiment, the container 44 is an example of a heat transfer member.

The type of the refrigerant RF is not limited as long as heat may be transferred by circulating the refrigerant RF while performing a phase transition between a liquid phase and a gas phase in the container 44, and for example, water may be used. Although oil or alcohol may be used instead of water, water is easily available and easy to handle, and water is used also in the present embodiment.

The heat reception unit 46 is a portion that is arranged in contact with the element 36 as illustrated in FIG. 3, and receives heat of the element 36. The heat reception unit 46 includes an evaporation unit 62 that vaporizes the refrigerant RF in the liquid phase by the heat.

The heat radiation unit 48 is a portion that is arranged separately from the heat reception unit 46 and releases heat of the refrigerant RF sealed in the container 44 to the outside. The heat radiation unit 48 includes a condensation unit 72 that liquefies the refrigerant RF in the gas phase by heat radiation.

The connection unit 50 is a portion connecting the heat reception unit 46 and the heat radiation unit 48. In addition, the connection unit 50 is also a movement region 74 in which the refrigerant RF moves between the evaporation unit 62 and the condensation unit 72. Note that a part of heat of the refrigerant RF in the gas phase state is discharged to the outside also at the connection unit 50, and the refrigerant RF is liquefied.

In the drawings, a width direction, a depth direction, and a height direction of the container 44 are indicated by an arrow W, an arrow D, and an arrow H, respectively. In the present embodiment, the heat radiation unit 48 has a shape wider in the width direction and shorter in the depth direction than the heat reception unit 46. The connection unit 50 is narrower in the width direction than the heat reception unit 46, and has a depth for connecting the heat reception unit 46 and the heat radiation unit 48.

In the present embodiment, when the container 44 is viewed in a thickness direction, the heat reception unit 46, the heat radiation unit 48, and the connection unit 50 have a symmetrical shape with a center line CL as a center. In addition, the element 36 is in contact with the container 44 on the center line CL at the heat reception unit 46. With this configuration, a temperature distribution of the container 44 that has received heat of the element 36 becomes a distribution close to symmetry with the center line CL as a center.

As illustrated in FIG. 2, the container 44 has a structure in which two plate materials, a bottom plate 52 and a top plate 54, are fixed in a state of being stacked in a thickness direction (height direction).

A plurality of columns 56 is erected from the bottom plate 52. Tips (upper ends) of the columns 56 are in contact with the top plate 54, and the top plate 54 is supported by the columns 56. The inside of the container 44 is maintained in a low pressure state, and even in the low pressure state, the columns 56 maintain an interval between the top plate 54 and the bottom plate 52 and secure an internal volume of the container 44.

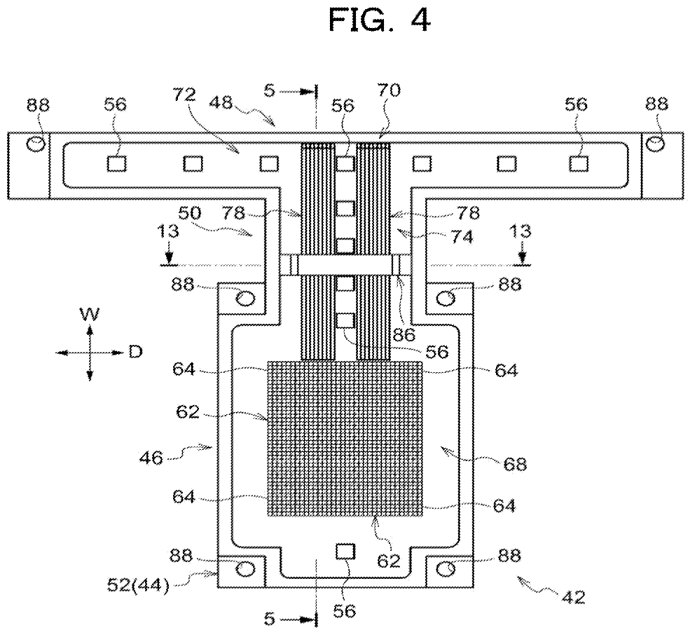

In the present embodiment, as illustrated in FIGS. 2 and 4, a plurality of the columns 56 is arranged in the heat radiation unit 48 at intervals in the width direction of the container 44, and a plurality of the columns 56 is further arranged in the connection unit 50 at intervals in the depth direction of the container 44. In addition, also in the heat reception unit 46, one column 56 is provided on an opposite side of the connection unit 50 with the evaporation unit 62 in between.

As illustrated in FIG. 2, in the bottom plate 52, an opening 58 is formed in a portion of the heat reception unit 46. By fitting a heat reception plate 60 into the opening 58, a sealed structure in the container 44 is achieved by the bottom plate 52, the top plate 54, and the heat reception plate 60.

On the heat reception plate 60, a plurality of column members 64 is erected toward the top plate 54. As illustrated in detail also in FIGS. 5 to 7, the plurality of column members 64 is arranged at regular intervals in the width direction and the depth direction, and grid-like grooves 66 are formed between the column members 64. A groove width W1 of the groove 66 is narrower than an inner diameter N1 of a transport pipe 78 described later.

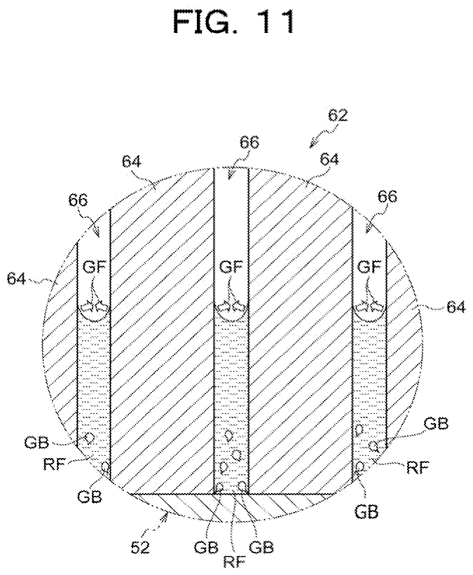

As illustrated in FIG. 11, in the groove 66, vaporization of the refrigerant RF in the liquid phase is promoted by heat from the heat reception unit 46 (see FIGS. 1 to 4). This “vaporization” includes, in addition to “evaporation” indicating vaporization from a surface of the refrigerant RF as indicated by arrows GF, “boiling” indicating vaporization from the inside of the refrigerant RF as indicated by bubbles GB. Hereinafter, “evaporation” will be used to refer to both of these. A portion including the column members 64 is a portion where the refrigerant RF in the liquid phase evaporates in this way, and is the evaporation unit 62.

Tips of the column members 64 are in contact with the top plate 54. Also with this configuration, under the low pressure state inside the container 44, the interval between the top plate 54 and the bottom plate 52 is maintained, and the internal volume of the container 44 is secured.

As illustrated in FIG. 4, around the column members 64, a diffusion region 68 is formed between the top plate 54 and the bottom plate 52. The refrigerant RF in the gas phase evaporated in the evaporation unit 62 diffuses into the diffusion region 68.

Moreover, the movement region 74 is formed between the heat reception unit 46 and the heat radiation unit 48, between the top plate 54 and the bottom plate 52. The refrigerant RF in the gas phase evaporated in the evaporation unit 62 moves to the heat radiation unit 48 through the movement region 74. During this movement, heat of the refrigerant RF is discharged to the outside of the container 44, so that the refrigerant RF in the gas phase is condensed and liquefied. For example, the connection unit 50 and the heat radiation unit 48 are also portions where the refrigerant RF in the gas phase is condensed in this way.

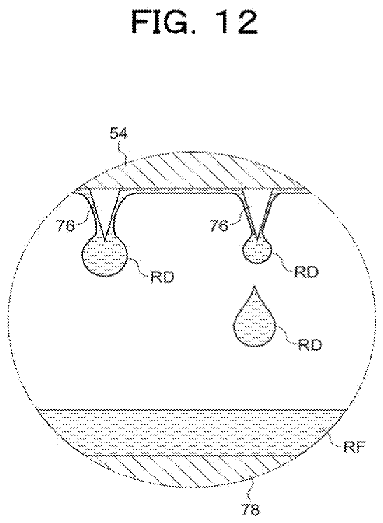

As illustrated in FIG. 12, a plurality of protrusions 76 is formed on the top plate 54 toward a bottom portion of the bottom plate 52 (see FIG. 5). Each of the protrusions 76 has a shape that tapers toward a tip side. By providing such protrusions 76, as compared with a structure without the protrusions 76, a surface area of a top surface in the condensation unit 72 is larger.

As illustrated in FIGS. 4 to 6, a transport unit 70 is arranged between the evaporation unit 62 and the condensation unit 72 inside the container 44. For example, the evaporation unit 62 and the transport unit 70 are arranged in a set corresponding to the condensation unit 72.

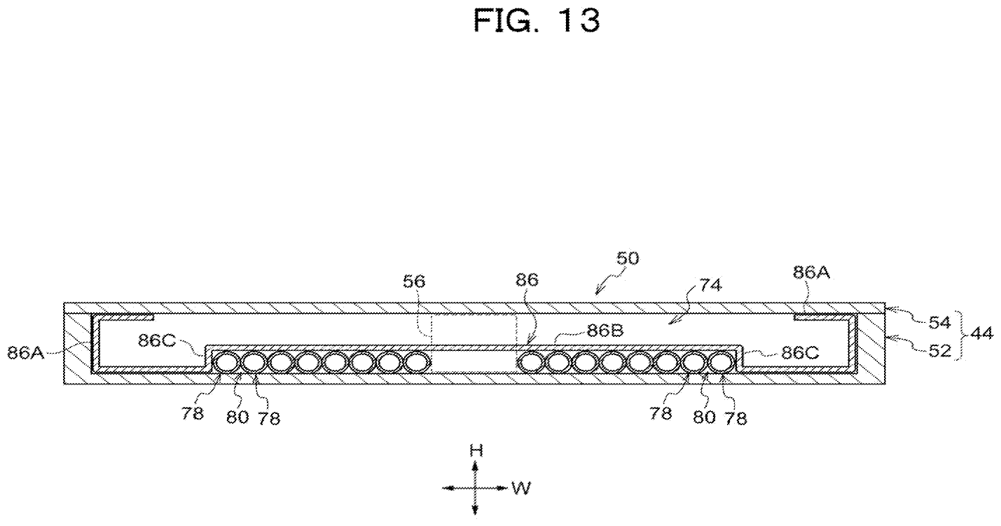

The transport unit 70 has the transport pipes 78 extending in the depth direction. In the transport unit 70, one transport pipe 78 may be arranged, but in the present embodiment, a plurality of transport pipes 78 is arranged in the transport unit 70. For example, in an example illustrated in FIG. 13, in the transport unit 70, a set of eight transport pipes 78 arranged adjacent to each other in the width direction is arranged in two sets with the column 56 in between, and a total of 16 transport pipes 78 are arranged. A longitudinal direction of the transport pipe 78 coincides with the depth direction of the container 44 (arrow D direction).

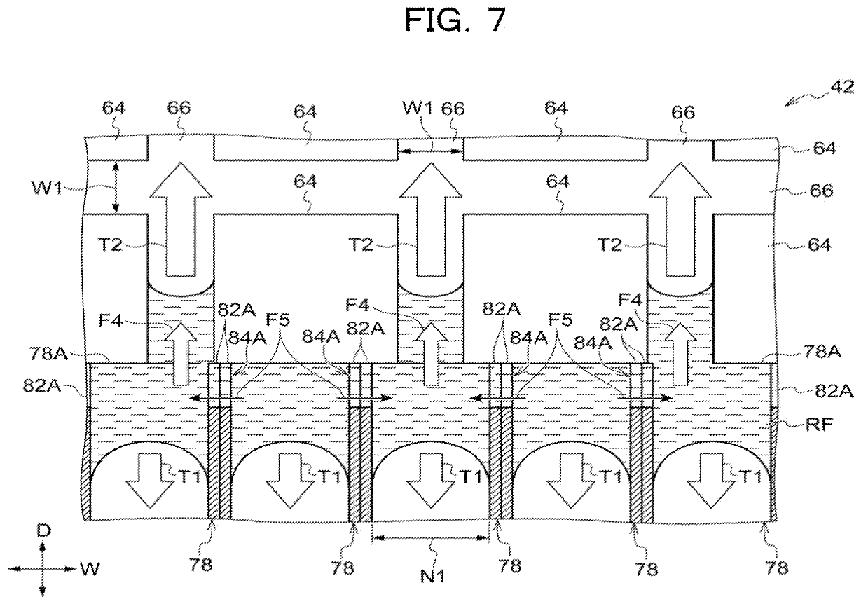

As illustrated in FIG. 7, the inner diameter N1 of the transport pipe 78 is set such that the refrigerant RF in the liquid phase may be transported by a capillary phenomenon and a sufficient amount of the refrigerant RF may be transported to the evaporation unit 62 by the whole of the plurality of transport pipes 78.

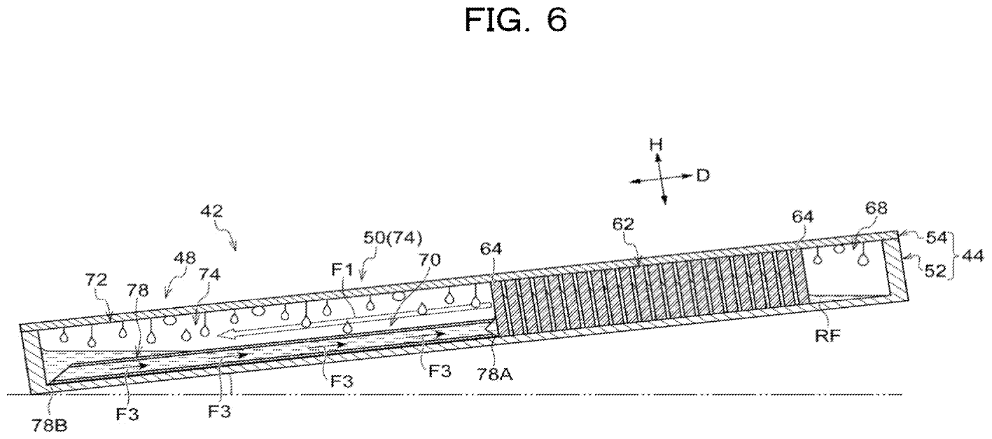

Moreover, an upper limit of the inner diameter N1 of the transport pipe 78 is determined so that the refrigerant RF may be transported from another end portion 78B to one end portion 78A by the capillary phenomenon even in a case where the cooling device 42 is inclined such that the one end portion 78A is higher than the another end portion 78B (see FIG. 6). For example, the inner diameter N1 of the transport pipe 78 is set to the inner diameter N1 that may secure a flow rate within a range where the capillary phenomenon occurs in this way, and the inner diameter N1 of the transport pipe 78 is wider than the groove width W1 of the groove 66 of the evaporation unit 62.

Note that, in the present embodiment, as illustrated in FIG. 13, spaces 80 between the transport pipes 78 arranged adjacent to each other in the width direction and the bottom plate 52 are also regions capable of transporting the refrigerant RF in the liquid phase by the capillary phenomenon.

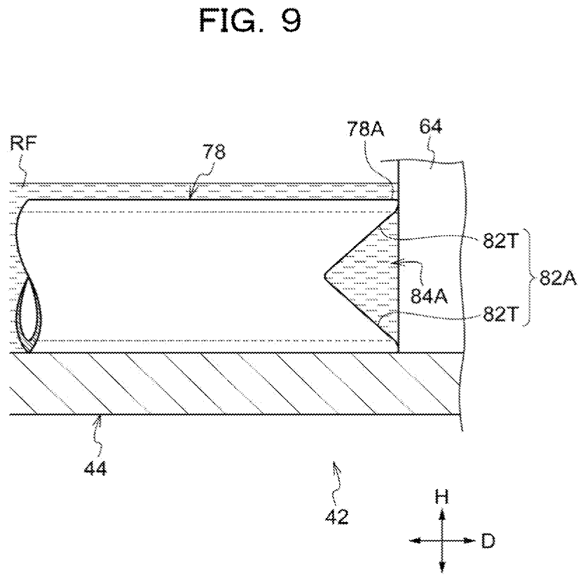

The one end portions 78A of the transport pipes 78 face the column members 64, as also illustrated in FIGS. 7 and 9. In the first embodiment, a gap portion is provided at the one end portion 78A. For example, by cutting out the transport pipe 78 at the one end portion, an inclined portion 82A is formed so as to be inclined relative to the longitudinal direction of the transport pipe 78. The inclined portion 82A is an example of the gap portion in the first embodiment.

For example, in the present embodiment, as illustrated in FIG. 9, the inclined portion 82A has a V-shape having a pair of inclined surfaces 82T formed so as to approach each other as they are separated from the column members 64.

A portion where the inclined portion 82A is provided, which is a region between the inclined surfaces 82T, is a gap 84A in which the refrigerant RF in the liquid phase moves from the transport pipe 78 to the evaporation unit 62.

A plurality of the inclined portions 82A is formed in one transport pipe 78 at regular intervals in a circumferential direction. In the present embodiment, as illustrated in FIG. 7, two inclined portions 82A are formed in one transport pipe 78 so as to be separated from each other in the width direction of the container 44 (arrow W direction).

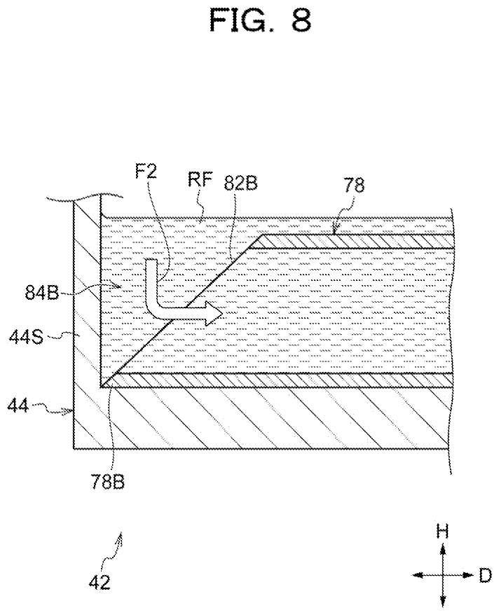

The another end portion 78B of the transport pipe 78 faces a side wall 44S of the container 44, as illustrated in FIG. 8. The side wall 44S is a side wall forming an end on a front side in the depth direction (condensation unit 72 side).

A second gap portion is provided in the another end portion 78B of the transport pipe 78. For example, a second inclined portion 82B is formed by inclining the another end portion 78B in one direction relative to the longitudinal direction of the transport pipe 78, and a region between the side wall 44S and the second inclined portion 82B is a second gap 84B in which the refrigerant RF in the liquid phase moves from the condensation unit 72 into the transport pipe 78.

As also illustrated in FIG. 13, a fixture 86 is arranged inside the container 44 at a portion of the connection unit 50. The fixture 86 includes fitting portions 86A fitted between the top plate 54 and the bottom plate 52 on both sides in the width direction (arrow W direction), and a pressing portion 86B that presses the plurality of transport pipes 78 toward the bottom plate 52 at the center in the width direction. The transport pipes 78 are pressed and fixed to the bottom plate 52 by the pressing portion 86B. Since the plurality of transport pipes 78 is fixed in contact with the bottom plate 52, a sufficient flow path cross-sectional area is secured between the top plate 54 and the transport pipe 78 for substantially moving the refrigerant RF in the gas phase.

Moreover, since the sets of the transport pipes 78 are positioned between the column 56 and side surface portions 86C of the pressing portion 86B, the sets are also held in the width direction.

As illustrated in FIGS. 1 to 4, the bottom plate 52 of the container 44 is provided with fastening holes 88. Fasteners such as screws are inserted into the fastening holes 88 and fastened to the substrate 34 to fix the cooling device 42 to the substrate 34. Since the element 36 to be cooled is mounted on the substrate 34, the cooling device 42 is also fixed to the element 36.

Note that the top plate 54 has a shape that avoids the fastening holes 88 when viewed in an overlapping direction with the bottom plate 52 (arrow A1 direction illustrated in FIG. 1). Thus, when the cooling device 42 is fixed to the substrate 34, it is possible to perform a fastening operation (for example, a screw turning operation) on the fasteners without being disturbed by the top plate 54.

As illustrated in FIGS. 1 and 2, a downstream heat radiation member 100L and an upstream heat radiation member 100U are attached to the top plate 54. Both the downstream heat radiation member 100L and the upstream heat radiation member 100U include a plurality of fins 90. These fins 90 are arranged along a flow direction of cooling air from a fan (not illustrated) (arrow AF direction). In the following, as appropriate, the fins provided on the downstream heat radiation member 100L will be referred to as downstream fins 90L, and the fins provided on the upstream heat radiation member 100U will be referred to as upstream fins 90U to distinguish these fins.

In the first embodiment, each of the plurality of fins 90 has a rectangular plate shape having a flat surface.

The heat of the element 36 is transferred to the downstream heat radiation member 100L and the upstream heat radiation member 100U via the container 44, and is radiated from the downstream heat radiation member 100L and the upstream heat radiation member 100U. In the first embodiment, the container 44 is also an example of a heat transfer member that transfers the heat of the element 36 to the downstream heat radiation member 100L and the upstream heat radiation member 100U in this way.

In addition, the fins 90 increase a substantial surface area of the container 44, which is a heat radiation area for heat radiation to the outside (air cooling). For example, in the present embodiment, the fins 90 are installed in substantially an entire area of the top plate 54, and a wide heat radiation area is secured.

The downstream heat radiation member 100L is arranged at a position corresponding to the heat reception unit 46, and the upstream heat radiation member 100U is arranged at a position corresponding to the heat radiation unit 48. The upstream heat radiation member 100U is arranged on an upstream side in the flow direction of the cooling air relative to the downstream heat radiation member 100L.

In the top plate 54, a portion to which the upstream heat radiation member 100U is attached (portion corresponding to the connection unit 50 and the heat radiation unit 48) supports the upstream heat radiation member 100U, and is an upstream support plate 54U. Similarly, a portion to which the downstream heat radiation member is attached (portion corresponding to the heat reception unit 46) supports the downstream heat radiation member 100L, and is a downstream support plate 54L.

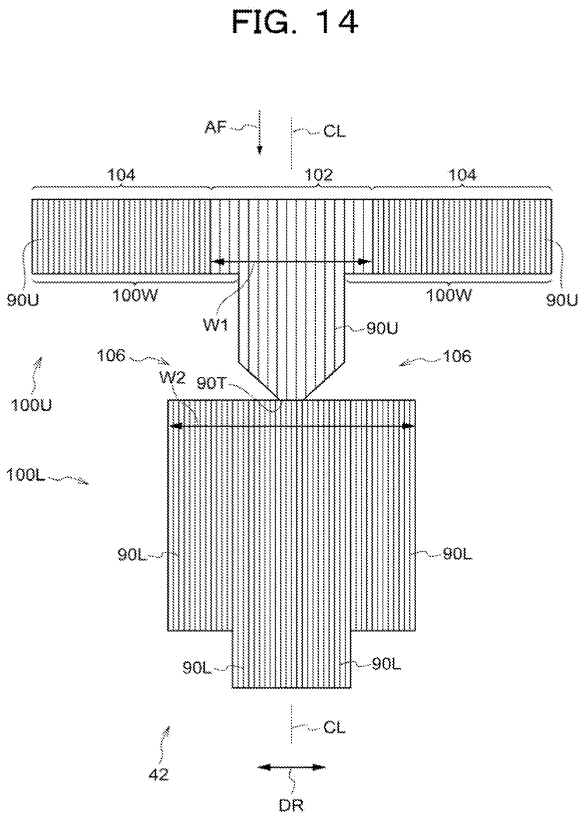

In the first embodiment, the heat radiation unit 48 is wider in the width direction than the connection unit 50. Thus, as also illustrated in FIG. 14, in the upstream heat radiation member 100U, there are wide portions 100W which are wider than a portion arranged on the connection unit 50 in a portion arranged on the heat radiation unit 48. For example, in the example illustrated in FIG. 14, the wide portions 100W are wider than the downstream heat radiation member 100L.

As illustrated in FIGS. 1 and 2, the bottom plate 52 of the container 44 is formed with recesses 108 on a surface corresponding to the substrate 34. The recesses 108 are formed on a central portion side of the upstream support plate 54U. In a portion where the recesses 108 are formed in a state where the cooling device 42 is mounted on the substrate 34, the upstream heat radiation member 100U becomes a penetration portion 110 penetrating in the flow direction of the cooling air. The cooling air flows to a downstream side through the penetration portion 110.

In the upstream heat radiation member 100U and the downstream heat radiation member 100L, a fin arrangement direction of the fins 90 (arrow DR direction) is a direction orthogonal to the flow direction of the cooling air (arrow AF direction).

In the upstream heat radiation member 100U, an interval between the upstream fins 90U at a central portion in the fin arrangement direction is longer than an interval between the upstream fins 90U at both ends in the fin arrangement direction. For example, in the upstream heat radiation member 100U, the central portion in the width direction is a low density portion 102 in which arrangement density of the upstream fins 90U is relatively lower than that of both ends, and both ends in the width direction are high density portions 104 in which the arrangement density of the upstream fins 90U is high. Note that the “arrangement density” is the number of fins 90 per unit length in the width direction. The low density portion 102 is an example of a low pressure loss portion in which pressure loss when the cooling air flows is small. A width W1 of the low density portion 102 is narrower than a width W2 of the downstream heat radiation member 100L.

Note that, in the first embodiment, arrangement density of the downstream fins 90L in the downstream heat radiation member 100L is equal to the arrangement density of the upstream fins 90U in the high density portions 104 of the upstream heat radiation member 100U. In this way, by densely arranging the downstream fins 90L in the downstream heat radiation member 100L, high heat radiation performance may be obtained.

The upstream heat radiation member 100U is arranged with a gap 106 in the flow direction of the cooling air from the downstream heat radiation member 100L. For example, the gap 106 is a space portion in which the fins 90 do not exist.

In the first embodiment, as illustrated in FIG. 14, downstream ends 90T of the upstream fins 90U in the low density portion 102 are in contact with the downstream heat radiation member 100L at the central portion in the width direction. In addition, on both sides in the width direction of the contact portion, the downstream ends 90T gradually approach the downstream heat radiation member 100L from the both sides in the width direction toward the central portion. Thus, the gap 106 of the first embodiment has a flat V-shape between the low density portion 102 and the downstream heat radiation member 100L.

Furthermore, the downstream heat radiation member 100L and the upstream heat radiation member 100U are both symmetrical in the width direction, and share the center line CL. In addition, when the container 44 is viewed in a plan view, the element 36 is positioned on the center line CL and at a position where the element 36 overlaps with the downstream heat radiation member 100L.

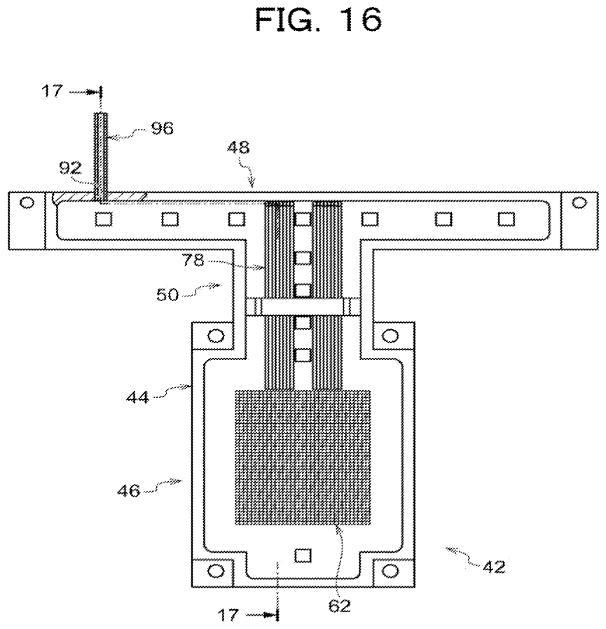

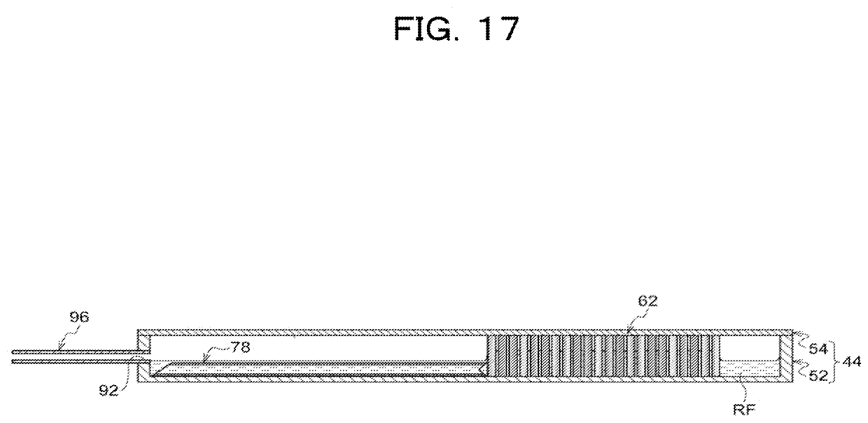

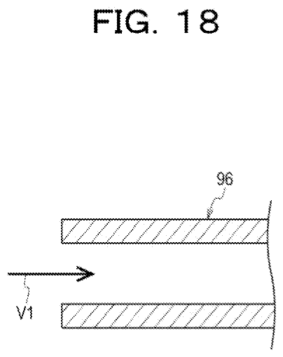

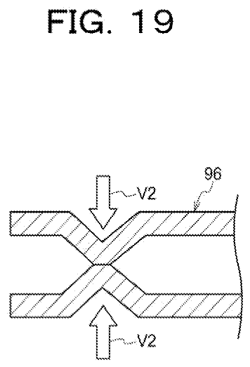

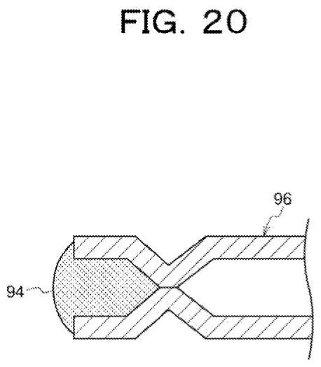

As illustrated in FIGS. 16 and 17, the container 44 is provided with an injection hole 92 that communicates the inside and the outside of the container 44. An injection pipe 96 extends from the injection hole 92 to the outside of the container 44. To inject the refrigerant RF into the container 44, air in the container 44 is discharged by using a vacuum pump or the like. Thereafter, as indicated by an arrow V1 in FIG. 18, the refrigerant is injected through the injection pipe 96. Then, the refrigerant in the container 44 is heated and boiled, and dissolved air in the refrigerant RF is discharged to the outside of the container 44. Note that this operation is not needed in the case of using a degassed refrigerant from which dissolved air has been removed in advance. Next, as indicated by arrows V2 in FIG. 19, the injection pipe 96 is compressed from the outside and sealed. Moreover, as illustrated in FIG. 20, the injection pipe 96 is more tightly sealed by filling a tip of the injection pipe 96 with a plug 94. For example, since the injection hole 92 is provided, the refrigerant RF may be injected into the inside of the container 44 through the injection hole 92. Then, after the injection, the injection hole 92 is sealed with the plug 94, so that the refrigerant RF may be sealed inside the container 44. Note that, in the drawings other than FIGS. 17 to 21, illustration of the injection hole 92, the plug 94, and the injection pipe 96 are omitted.

Next, operations of the present embodiment will be described.

As illustrated in FIG. 5, when the heat reception unit 46 receives heat from the element 36, the heat vaporizes the refrigerant RF in the liquid phase in the grooves 66 in the evaporation unit 62. For example, as also illustrated in FIG. 11, the refrigerant RF in the liquid phase becomes a gas phase due to evaporation from the surface of the refrigerant RF (see arrows GF) and boiling from the inside of the refrigerant RF (see bubbles GB).

The refrigerant RF in the gas phase is diffused into the diffusion region 68 and moves to the heat radiation unit 48 through the movement region 74 (see an arrow F1 of FIGS. 5 and 6). The cooling air from the fan flows along the longitudinal direction of the fins 90 (see the arrow AF in FIGS. 1 and 14).

In the diffusion region 68 and the movement region 74, a part of the refrigerant RF in the gas phase is condensed and liquefied by heat radiation through the fins 90. Moreover, the refrigerant RF that has reached the heat radiation unit 48 while maintaining the gas phase state is also cooled in the heat radiation unit 48 through the fins 90, so that the refrigerant RF is condensed and liquefied. By liquefying the refrigerant RF in the gas phase in this way, heat of condensation is released from the top plate 54 to the outside of the container 44. As a result, the heat of the element 36 is discharged into the air outside the container 44.

When the heat of the element 36 acts on the container 44, inside the container 44, the refrigerant RF in the liquid phase enters the inside of the transport pipe 78 from the another end portion 78B of the transport pipe 78, as indicated by an arrow F2 in FIG. 8. Moreover, the refrigerant RF is transported to the one end portion 78A, which is, toward the evaporation unit 62 by the capillary phenomenon, as indicated by arrows F3 in FIGS. 5 and 6. Furthermore, also in the spaces 80 between the transport pipes 78 and the bottom plate 52 (see FIG. 13), the refrigerant RF in the liquid phase is transported to the evaporation unit 62 by the capillary phenomenon.

Then, in the evaporation unit 62, the refrigerant RF in the liquid phase is evaporated and vaporized again in the grooves 66. In this way, inside the container 44, the refrigerant RF is circulated in the evaporation unit 62 and the condensation unit 72 while repeating the phase transition between the liquid phase and the gas phase. Since the heat received by the heat reception unit 46 may be transferred to the heat radiation unit 48, as described above, the heat may be transferred to the upstream heat radiation member 100U provided corresponding to the heat radiation unit 48, and the heat may be radiated from the upstream heat radiation member 1000.

As illustrated in FIG. 7, in the present embodiment, the groove width W1 of the groove 66 of the evaporation unit 62 is narrower than the inner diameter N1 of the transport pipe 78.

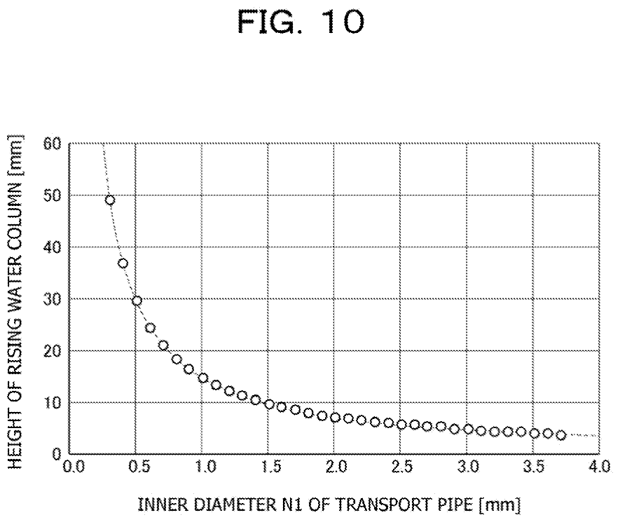

FIG. 10 illustrates a relationship between the inner diameter N1 of the transport pipe 78 and a rising height of a liquid column that rises in the transport pipe 78 due to the surface tension (capillary phenomenon), in a case where a liquid temperature is 25° C. This graph is an example of water used as the refrigerant RF in the present embodiment.

As is known from this graph, the smaller the inner diameter N1 of the transport pipe 78, the higher the rising height of the liquid column. For example, as the inner diameter N1 is smaller, the refrigerant RF may be raised with larger surface tension.

In the transport pipe 78, as indicated by the arrows F3 in FIGS. 5 and 6, the refrigerant RF in the liquid phase is transported to the evaporation unit 62. However, at the one end portion 78A of the transport pipe 78, as illustrated in FIG. 7, a suction force T1 to the refrigerant RF in a direction away from the evaporation unit 62 may act due to the surface tension of the refrigerant RF in the liquid phase inside. On the other hand, in the evaporation unit 62, a suction force T2 to the refrigerant RF that draws the refrigerant RF into the inside of the evaporation unit 62 may act due to the surface tension of the refrigerant RF in the liquid phase in the grooves 66. The suction force T1 and the suction force T2 are forces in opposite directions, but since the suction force T2 is larger, the refrigerant RF flows from the transport pipe 78 toward the evaporation unit 62 as indicated by arrows F4.

Here, for example, as illustrated in FIG. 6, a case is considered where the cooling device 42 is used in an inclined manner such that the one end portion 78A is higher than the another end portion 78B. As an example, it is assumed that the one end portion 78A is about 25 mm higher than the another end portion 78B. In this case, it may be seen that, when the inner diameter N1 of the transport pipe 78 is set to 0.6 mm or less, the refrigerant RF may be transported from the another end portion 78B toward the one end portion 78A in the transport pipe 78 due to the surface tension.

In this way, from the viewpoint of increasing the surface tension acting on the refrigerant RF in the transport pipe 78, it is sufficient that the inner diameter N1 of the transport pipe 78 is made smaller. Note that, when the inner diameter N1 of the transport pipe 78 is made smaller, the flow path cross-sectional area of the refrigerant RF also becomes smaller, so that the amount of the refrigerant RF that may be transported per unit time also becomes smaller. Thus, a lower limit value of the inner diameter N1 of the transport pipe 78 is determined from the viewpoint of securing the transport amount of the refrigerant RF per unit time.

As illustrated in FIG. 7, in the present embodiment, the groove width W1 of the groove 66 is narrower than the inner diameter N1 of the transport pipe 78. From the relationship illustrated in FIG. 10, the surface tension acting on the refrigerant RF in the liquid phase in the evaporation unit 62 is larger than the surface tension acting on the refrigerant RF in the liquid phase in the transport pipe 78. Thus, by a difference between the suction force T2 and the suction force T1, a force to move from the transport pipe 78 to the evaporation unit 62 may be caused to act, and the refrigerant RF may be moved from the transport pipe 78 to the evaporation unit 62.

Here, a structure in which the one end portion 78A of the transport pipe 78 is formed flat without providing the gap portion is considered. In the transport pipe having the flat one end portion 78A, when an opening portion of the transport pipe faces the column member 64 and an entire circumference of the opening portion is in contact with the column member 64, the opening portion may be covered by the column member 64. By increasing the inner diameter N1 of the transport pipe, it is possible to secure a range that is not covered by the column member 64 at the opening portion of the transport pipe. However, as described above, in order to ensure that the surface tension acts on the refrigerant RF, the inner diameter N1 has an upper limit.

On the other hand, in the present embodiment, the inclined portion 82A is provided at the one end portion 78A of the transport pipe 78 as an example of the gap portion. In addition, even when a tip portion of the one end portion 78A is in contact with the evaporation unit 62, the gap 84A is formed between the transport pipe 78 and the evaporation unit 62 so that the one end portion 78A does not contact the evaporation unit 62. For example, the structure is such that the opening portion at the one end portion 78A of the transport pipe 78 is not completely blocked by the column member 64. Thus, as indicated by arrows F5 in FIG. 7, the refrigerant RF in the liquid phase transported by the transport pipe 78 flows into the groove 66 of the evaporation unit 62 through the gap 84A. For example, a structure is achieved that facilitates movement of the refrigerant RF in the liquid phase from the transport pipe 78 to the evaporation unit 62.

In the structure in which the groove width W1 of the groove 66 is narrower than the inner diameter N1 of the transport pipe 78 as described above, the column member 64 becomes relatively thick and covers a wide range of the opening portion of the transport pipe 78. However, even in such a structure, in the present embodiment, since the gap 84A is formed between the transport pipe 78 and the evaporation unit 62, the refrigerant RF in the liquid phase may be reliably moved from the transport pipe 78 to the evaporation unit 62.

In the first embodiment, the gap portion is the inclined portion 82A provided at the one end portion 78A of the transport pipe 78. When the gap portion is provided in the transport pipe 78 in this way, no other member for forming the gap 84A is needed, and the structure of the cooling device 42 may be simplified.

The gap portion is the inclined portion 82A in the example described above. For example, the gap 84A may be formed by the simple structure in which the one end portion 78A of the transport pipe 78 is inclined relative to the longitudinal direction of the transport pipe 78.

As illustrated in FIG. 9, the inclined portion 82A has the pair of inclined surfaces 82T. The inclined surfaces 82T are surfaces that approach each other as they are separated from the evaporation unit 62. By forming the inclined portion 82A including such inclined surfaces 82T, a structure may be achieved in which the gap 84A is formed without making the depth to cut the inclined portion 82A (the length of the portion cut from the evaporation unit 62 side) excessively long.

Note that the one end portion 78A of the transport pipe 78 may be provided with an inclined portion inclined in one direction in a similar manner to the second inclined portion 82B of the another end portion 78B.

Furthermore, the inclined portion 82A as an example of the gap portion is provided at a plurality of places (two places in the present embodiment) in the circumferential direction in one transport pipe 78. Since a plurality of the gaps 84A is formed by providing the plurality of gap portions, it is possible to secure a cross-sectional area of a portion where the refrigerant RF flows from the transport pipe 78 to the evaporation unit 62 wider, compared with that of a structure in which only one gap portion is provided in one transport pipe 78.

As illustrated in FIG. 8, the another end portion 78B of the transport pipe 78 is provided with the second inclined portion 82B as an example of the second gap portion, and the second gap 84B is formed between the another end portion 78B and the side wall 44S of the container 44. For example, the structure is such that the opening portion at the another end portion 78B of the transport pipe 78 is not blocked by the side wall 44S. Thus, a structure is achieved in which the refrigerant RF in the liquid phase in the container 44 easily flows into the inside of the transport pipe 78 through the second gap 84B.

In the first embodiment, the transport unit 70 includes the plurality of transport pipes 78. As the transport unit 70, for example, a plate-shaped member or the like having a hole formed as a flow path for the refrigerant RF in the liquid phase may be used instead of or in combination with the transport pipes 78. Since the transport unit 70 has the transport pipes 78, the transport unit 70 may be formed with a simple structure.

In addition, the plurality of transport pipes 78 is arranged in parallel. As described above, in terms of increasing the surface tension acting on the refrigerant RF in the liquid phase flowing through the transport pipe 78, since the inner diameter N1 of the transport pipe 78 has an upper limit, it is difficult to secure a sufficient flow rate with only one transport pipe 78. On the other hand, by arranging the plurality of transport pipes 78 in parallel, the transport pipes 78 may secure a larger flow rate as a whole.

Since the transport pipes 78 are fixed to the container 44 by the fixture 86, displacement or falling of the transport pipes 78 may be suppressed.

The plurality of transport pipes 78 is arranged so that a flow path for the refrigerant RF in the liquid phase is formed also between the two adjacent transport pipes 78 and the bottom plate 52. Since not only the inside of the transport pipe 78 but also the outside of the transport pipe 78 is used as a region where the refrigerant RF in the liquid phase flows, a larger flow rate of the refrigerant RF may be secured as compared with a structure in which such a flow path is not formed.

As illustrated in FIG. 4, the condensation unit 72 is formed wider in the width direction (arrow W direction) than the evaporation unit 62. In addition, in the upstream heat radiation member 100U, the portion arranged on the condensation unit 72 is the wide portions 100W (see FIG. 14) which are wider than the portion arranged on the connection unit 50. Thus, as compared with a structure in which such wide portions 100W are not formed, the upstream heat radiation member 100U may secure a wide range in which the cooling air is applied, and condensation of the refrigerant RF may be promoted.

In the first embodiment, the low density portion 102 having lower arrangement density of the upstream fins 90U than both ends is provided at the central portion in the width direction of the upstream heat radiation member 100U. In the low density portion 102, the arrangement density of the upstream fins 90U is lower than that in the high density portions 104 formed at both ends in the width direction, and pressure loss of the cooling air is also small.

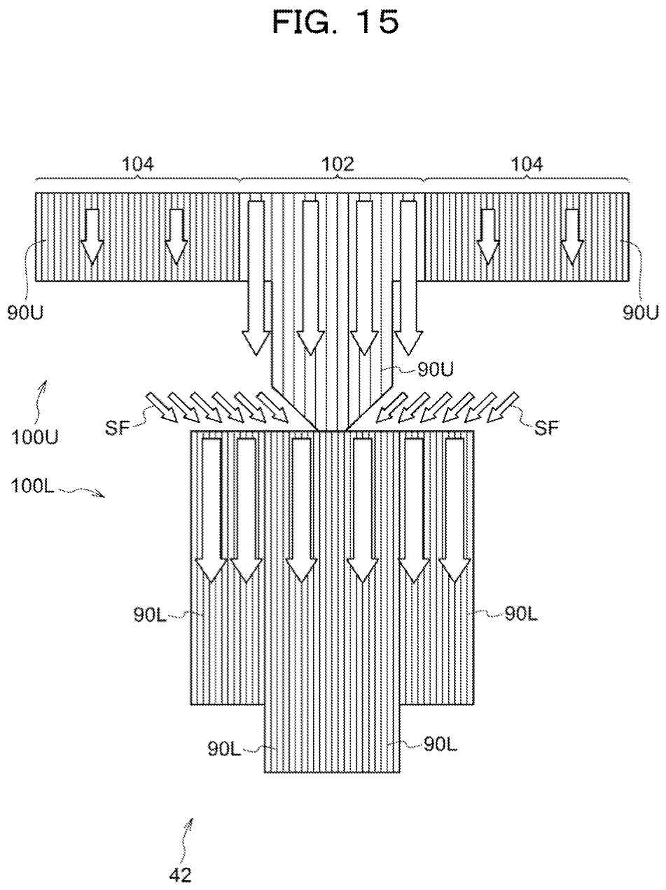

In FIG. 15, a state of the cooling air flowing through the upstream heat radiation member 100U and the downstream heat radiation member 100L is indicated by white arrows. In FIG. 15, the length of each arrow corresponds to a wind speed, and the longer the arrow, the faster the wind speed. Furthermore, an area of the arrow indicates an amount of heat radiated from the fins 90, and the larger the area of the arrow, the larger the amount of heat radiated.

Since pressure loss of the low density portion 102 is smaller than that of the high density portions 104, the wind speed of the cooling air is higher in the low density portion 102 than in the high density portions 104.

The gap 106 is provided between the upstream heat radiation member 100U and the downstream heat radiation member 100L. Since the wind speed of the cooling air increases in the low density portion 102, a venturi effect according to the Bernoulli's theorem occurs in the gap 106. For example, in the gap 106, pressure at the central portion corresponding to the low density portion 102 is lower than pressure at both ends corresponding to the high density portions 104. As a result, in the gap 106, as indicated by arrows SF in FIG. 15, a flow of air drawn from the sides of both ends to the central portion is generated. Since the downstream heat radiation member 100L is positioned on the downstream side of the low density portion 102, more cooling air may be applied to the downstream heat radiation member 100L as compared with a case where the low density portion 102 is not provided. For example, since the upstream heat radiation member 100U is a heat radiation member arranged corresponding to the heat reception unit 46, cooling efficiency may be improved by applying more cooling air to the downstream fins 90L at the positions where a cooling effect of the element 36 is large.

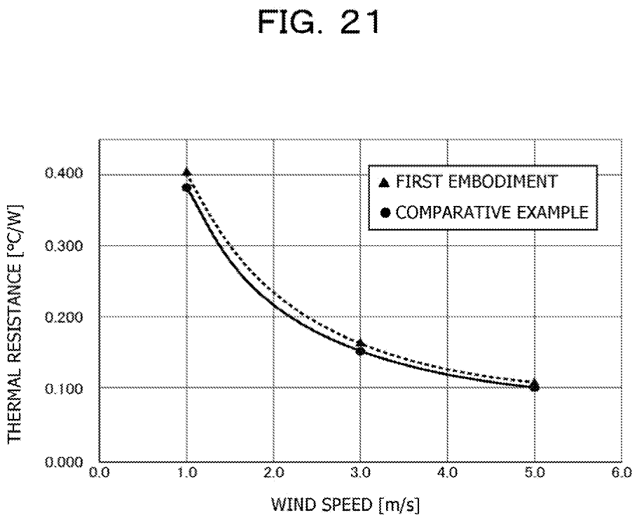

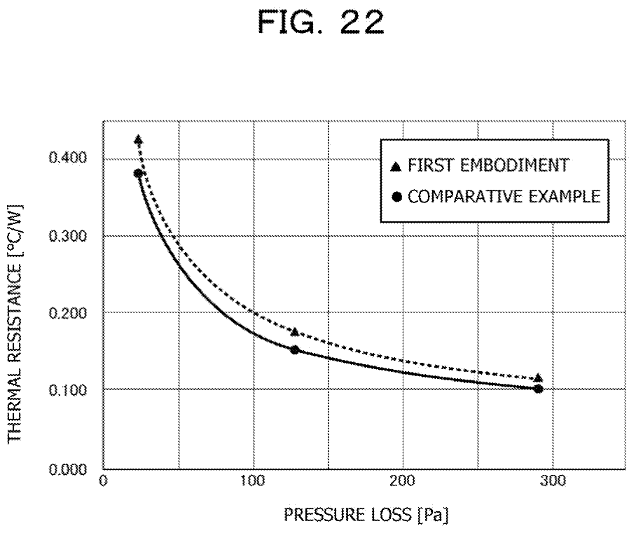

FIG. 21 illustrates a relationship between the wind speed of the cooling air generated by the fan and thermal resistance at each wind speed. Furthermore, FIG. 22 also illustrates pressure loss relative to the cooling air and thermal resistance at each pressure loss. The smaller a value of this thermal resistance, the lower temperature per unit thermal energy and the easier it is to transfer heat, so a heat radiation effect is higher. Note that, in the graphs of FIGS. 21 and 22, a solid line indicates the case of the first embodiment. On the other hand, a comparative example indicated by a broken line is a case where the portion of the low density portion 102 of the first embodiment is replaced with the high density portions 104, but other than this, the structure is the same as that of the first embodiment.

As is known from FIG. 21, the value of the thermal resistance decreases as the wind speed of the cooling air increases, but the value of the thermal resistance in the first embodiment is smaller than that in the comparative example regardless of the value of the wind speed. Furthermore, as is known from FIG. 22, the value of the thermal resistance decreases as the value of the pressure loss increases, but the value of the thermal resistance in the first embodiment is smaller than that in the comparative example regardless of the value of the pressure loss. In this way, it may be seen that, in the first embodiment, a smaller value is obtained as the value of the thermal resistance than in the comparative example, and higher cooling performance may be achieved.

The downstream ends 90T of the upstream fins 90U gradually approach the downstream heat radiation member 100L toward the central portion, and the gap 106 between the low density portion 102 and the downstream heat radiation member 100L has a V-shape in a plan view. With this configuration, as indicated by the arrows SF in FIG. 15, it is possible to effectively generate an air flow flowing to the downstream heat radiation member 100L from both ends in the width direction toward the central portion in the gap 106. In the downstream heat radiation member 100L, since the element 36 is arranged in contact with the central portion, a high cooling effect on the element 36 may be obtained.

The upstream heat radiation member 100U and the downstream heat radiation member 100L share the center line CL. Since the central portion of the downstream heat radiation member 100L, which is the portion in contact with the element 36, is positioned downstream of the central portion of the upstream heat radiation member 100U, by effectively applying the cooling air to the central portion of the downstream heat radiation member 100L, a high cooling effect on the element 36 may be obtained.

In a state where the cooling device 42 is mounted on the substrate 34, the recesses 108 are the penetration portion 110 of the upstream heat radiation member 100U. The penetration portion 110 penetrates the bottom plate 52 in the flow direction of the cooling air, and the cooling air flows to the downstream side through the penetration portion 110 and is applied to the downstream heat radiation member 100L. Thus, a higher cooling effect may be obtained in the downstream heat radiation member 100L as compared with a structure in which the penetration portion 110 is not formed.

Next, a second embodiment will be described. In the second embodiment, elements, members, and the like similar to those in the first embodiment are denoted by the same reference signs as those in the first embodiment, and detailed description thereof will be omitted.

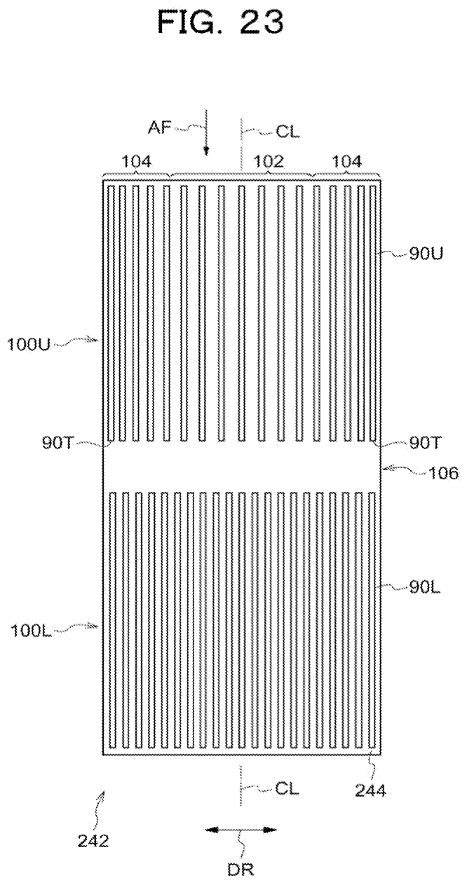

As illustrated in FIG. 23, a cooling device 242 of the second embodiment includes a heat transfer plate 244 instead of the container 44 of the first embodiment (see FIGS. 2 to 4). In the example illustrated in FIG. 23, the heat transfer plate 244 has a rectangular shape when viewed in a plate thickness direction, and an element 36 is in contact with one surface (surface facing a substrate 34) thereof. The heat transfer plate 244 is a solid plate-shaped member formed from the same material as fins 90, for example, copper or aluminum.

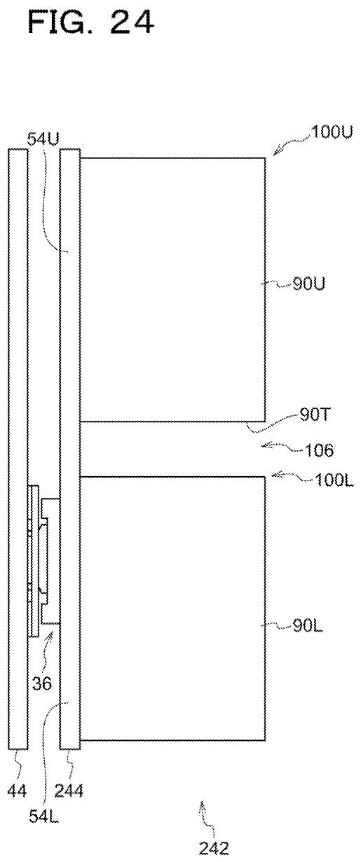

As also illustrated in FIG. 24, a downstream heat radiation member 100L and an upstream heat radiation member 100U are attached to the heat transfer plate 244. Also in the second embodiment, similarly to the first embodiment, the downstream heat radiation member 100L and the upstream heat radiation member 100U include downstream fins 90L and upstream fins 90U, respectively. In the second embodiment, these fins 90 are arranged along a long side direction of the heat transfer plate 244. In addition, in the upstream heat radiation member 100U, a low density portion 102 is formed at a central portion in a width direction, and high density portions 104 are formed at both ends in the width direction.

Furthermore, in the second embodiment, the element 36 is in contact with the heat transfer plate 244 on a downstream side when the heat transfer plate 244 is viewed in a plan view.

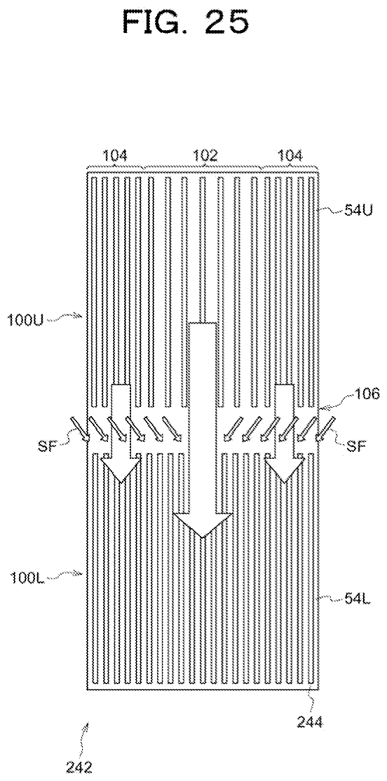

Also in the cooling device 242 of the second embodiment having such a structure, as indicated by white arrows in FIG. 25, a wind speed of cooling air is higher in the low density portion 102 than in the high density portions 104. In addition, as the wind speed of the cooling air in the low density portion 102 increases, air flows in a gap 106 so as to be drawn into the central portion from the sides of the both ends in a fin arrangement direction, as indicated by the arrows SF in FIG. 25. With this configuration, cooling performance for the element 36 may be improved.

Next, a third embodiment will be described. In the third embodiment, similar elements, members, and the like to those in the first embodiment or the second embodiment are denoted by the same reference signs as those in the first embodiment or the second embodiment, and detailed description thereof will be omitted. Furthermore, since an overall structure of a cooling device 342 of the third embodiment is similar to that of the cooling device 242 of the second embodiment, illustration thereof is omitted.

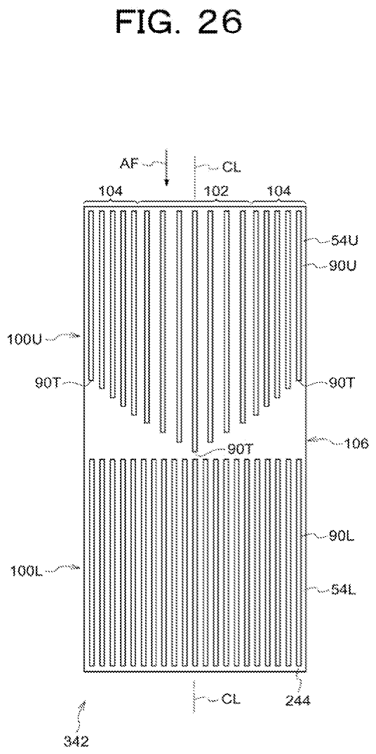

In the cooling device 342 of the third embodiment, as illustrated in FIG. 26, downstream ends 90T of a plurality of upstream fins 90U gradually approach a downstream heat radiation member 100L from both sides in a fin arrangement direction toward a center line CL.

Therefore, in the third embodiment, in a gap 106 between an upstream heat radiation member 100U and the downstream heat radiation member 100L, air flows along the downstream ends 90T of the upstream fins 90U, so that the air to a central portion of the downstream heat radiation member 100L may be effectively guided.

Next, a fourth embodiment will be described. In the fourth embodiment, similar elements, members, and the like to those in the first embodiment to the third embodiment are denoted by the same reference signs as those in the first embodiment to the third embodiment, and detailed description thereof will be omitted. Furthermore, since an overall structure of a cooling device 442 of the fourth embodiment is similar to that of the cooling device 242 of the second embodiment, illustration thereof is omitted.

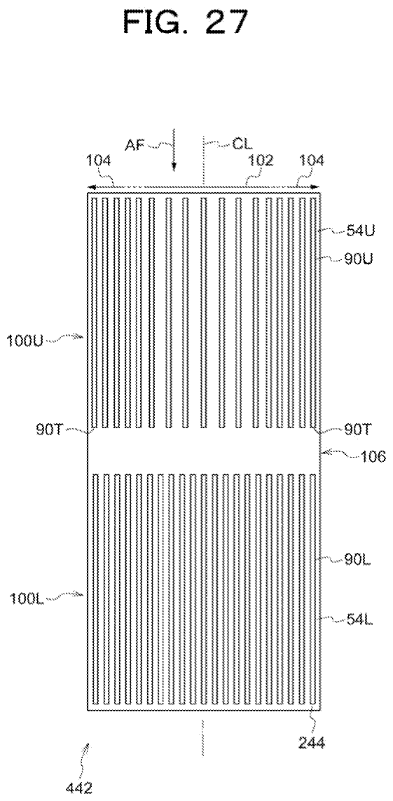

In the cooling device 442 of the fourth embodiment, as illustrated in FIG. 27, in an upstream heat radiation member 100U, a fin interval continuously changes between a low density portion 102 at the center and high density portions 104 at both ends in a fin arrangement direction.

In this way, a structure may be achieved in which, even when the fin interval continuously changes in the upstream heat radiation member 100U, pressure loss is made relatively lower at the center than at both ends in the fin arrangement direction, and a wind speed of cooling air becomes faster.

Note that, on the other hand, for example, in the first embodiment and the second embodiment, the structure is adopted in which the fin interval intermittently changes between the low density portion 102 and the high density portions 104. With this configuration, the low density portion 102 and the high density portions 104 are clearly separated. In addition, the structure may be achieved in which, in the downstream heat radiation member 100L, the wind speed of the cooling air increases at the central portion in the fin arrangement direction.

Next, a fifth embodiment will be described. In the fifth embodiment, similar elements, members, and the like to those in the first embodiment to the fourth embodiment are denoted by the same reference signs as those in the first embodiment to the fourth embodiment, and detailed description thereof will be omitted. Furthermore, since an overall structure of a cooling device 542 of the fifth embodiment is similar to that of the cooling device 242 of the second embodiment, illustration thereof is omitted.

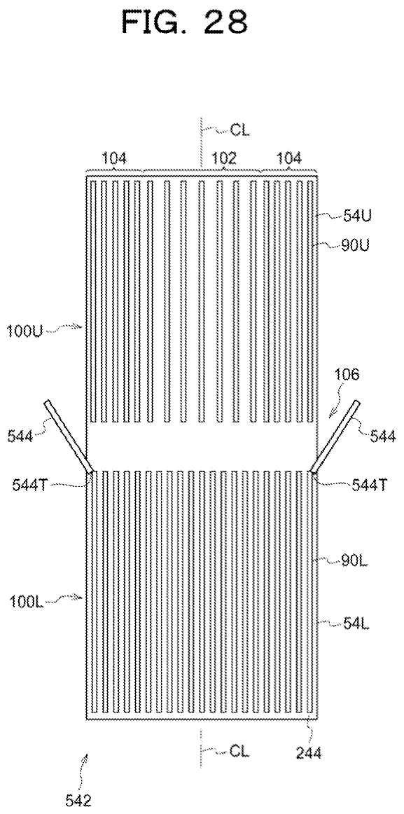

In the cooling device 542 of the fifth embodiment, as illustrated in FIG. 28, inclined plates 544 are provided on both sides of a gap 106 in a fin arrangement direction. The inclined plates 544 are inclined toward a center line CL from an upstream side to a downstream side. Downstream side ends 544L of the inclined plates 544 are attached to positions of long sides of a heat transfer plate 244. In addition, upstream sides of the inclined plates 544 protrude outward from the heat transfer plate 244 in the fin arrangement direction in a plan view of the heat transfer plate 244.

In the fifth embodiment, since the inclined plates 544 having such a structure are provided, air flowing outside an upstream heat radiation member 100U may be guided to the gap 106 along the inclined plates 544. With this configuration, an amount of wind flowing from the gap 106 to a downstream heat radiation member 100L is larger than that in a structure without the inclined plates 544.

Next, a sixth embodiment will be described. In the sixth embodiment, similar elements, members, and the like to those in the first embodiment to the fifth embodiment are denoted by the same reference signs as those in the first embodiment to the fifth embodiment, and detailed description thereof will be omitted. Furthermore, since an overall structure of a cooling device 642 of the sixth embodiment is similar to that of the cooling device 242 of the second embodiment, illustration thereof is omitted.

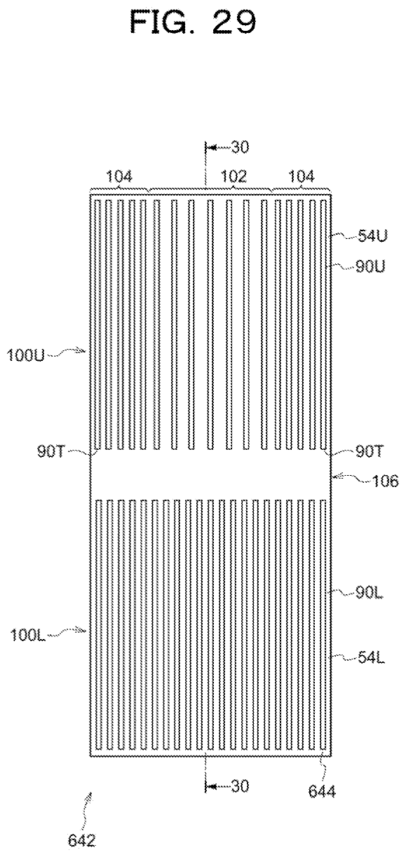

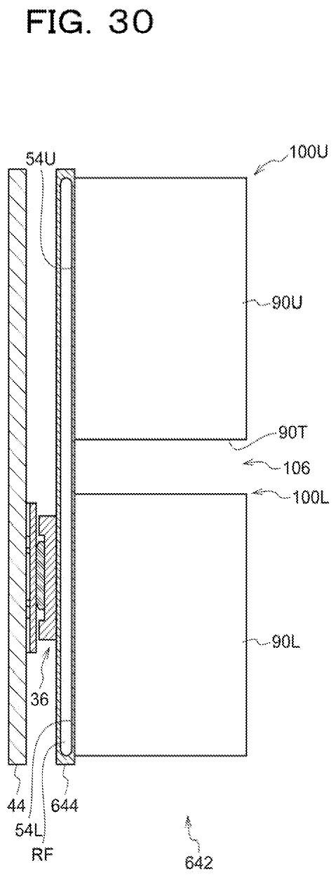

The cooling device 642 of the sixth embodiment includes a container 644 instead of the heat transfer plate 244, as illustrated in FIGS. 29 and 30. The container 644 is an example of a heat transfer member.

The container 644 has an outer shape similar to that of the heat transfer plate 244, but a refrigerant RF is sealed inside. The refrigerant RF of the sixth embodiment is a fluid that transfers heat by a phase transition between a gas phase and a liquid phase, like the refrigerant RF of the first embodiment. In the sixth embodiment, since a downstream side of the container 644 is a heat reception unit 46 in contact with an element 36, the refrigerant RF receives heat from the element 36 on the downstream side, undergoes a phase transition from the liquid phase to the gas phase, and moves to an upstream side. Furthermore, the upstream side of the container 644 is a heat radiation unit 48, and the refrigerant RF radiates heat on the upstream side, undergoes a phase transition from the gas phase to the liquid phase, and moves to the downstream side.

In the sixth embodiment, by using such a refrigerant RF, heat may be efficiently transferred and diffused in the container 644, and heat radiation from an upstream heat radiation member 100U may be promoted.

In the technology of the present disclosure, the fins may have a flat surface like the fins 90 described above, but may have, for example, a shape of each of the following modifications.

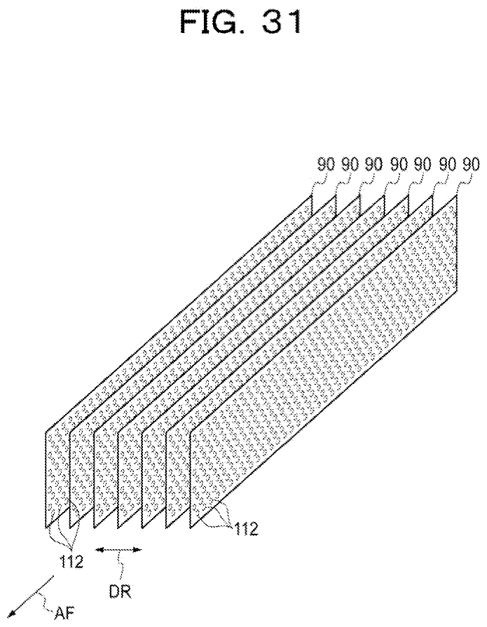

In fins 90 of a first modification illustrated in FIG. 31, minute irregularities 112 are formed on surfaces. Since the fins 90 having such irregularities 112 have a larger surface area than that of the fins 90 having flat surfaces, a heat radiation effect is also high.

Furthermore, in the fins 90 of the first modification, since the irregularities 112 are formed, pressure loss is higher than that of the fins 90. In addition, a value of the pressure loss may be adjusted by increasing or decreasing sizes of the irregularities 112 and the number of the irregularities 112 per unit area. For example, a structure may be exemplified in which, in the upstream heat radiation member 100U of each of the embodiments described above, the fins 90 having a relatively small number of irregularities 112 are arranged at the central portion in the fin arrangement direction and the fins having a relatively large number of irregularities 112 are arranged at both ends. With such a structure, a structure may be achieved in which a low pressure loss portion is formed in the central portion and high pressure loss portions are formed in both ends.

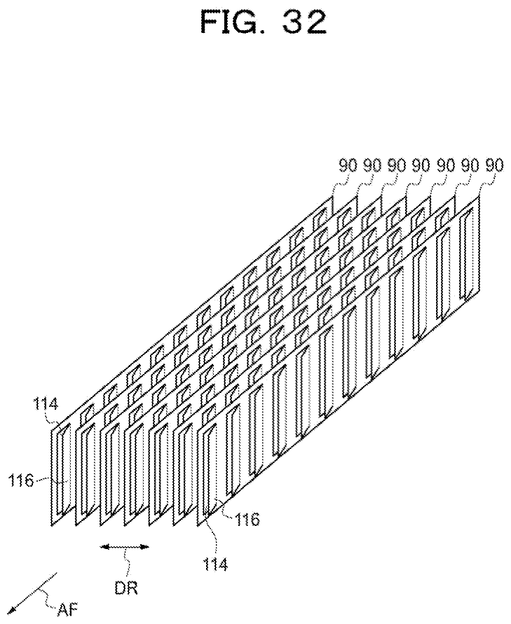

In fins 90 of a second modification illustrated in FIG. 32, a plurality of rectangular through holes 114 is formed along the longitudinal direction. In the example illustrated in FIG. 32, a plurality of cut-and-raised pieces 116 is formed on the fins 90. Each of the cut-and-raised pieces 116 is cut and raised so as to be inclined relative to the flow direction of the cooling air from the upstream side to the downstream side in the flow direction of the cooling air. In addition, portions hollowed out by forming the cut-and-raised pieces 116 in the fins 90 are the through holes 114.

In the fins 90 of the second modification, it is possible to adjust the value of the pressure loss by increasing or decreasing the sizes of the through holes 114 and an area ratio of the through holes 114 (ratio of the substantial surface area to the fins 90 in which the through holes 114 are not formed). For example, a structure may be achieved in which, in the upstream heat radiation member 100U of each of the embodiments described above, by arranging the fins 90 having a relatively small number of through holes 114 at the central portion in the fin arrangement direction and arranging the fins having a relatively large number of through holes 114 at both ends, the low pressure loss portion is formed in the central portion and the high pressure loss portions are formed in both ends.

Furthermore, in the fins 90 of the second modification, by the cut-and-raised pieces 116, an area where the cooling air is applied is wider than that of the fins 90 without such cut-and-raised pieces 116 when viewed from the upstream side of the cooling air, it is possible to obtain a high heat radiation effect.

In each of the embodiments described above, the examples in which the low pressure loss portion is formed in the central portion in the fin arrangement direction of the upstream heat radiation member 100U are given. However, for example, the low pressure loss portion may be formed in the end in the fin arrangement direction of the upstream heat radiation member 100U. When the low pressure loss portion is formed in the central portion in the fin arrangement direction, a portion having a high wind speed of the cooling air may be generated in the central portion. Thus, in the gap 106, a structure may be achieved in which wind is drawn from both sides toward the central portion.

Furthermore, in each of the embodiments described above, the structure in which a gap is provided between the transport pipe 78 and the evaporation unit 62 is also not limited to that described above.

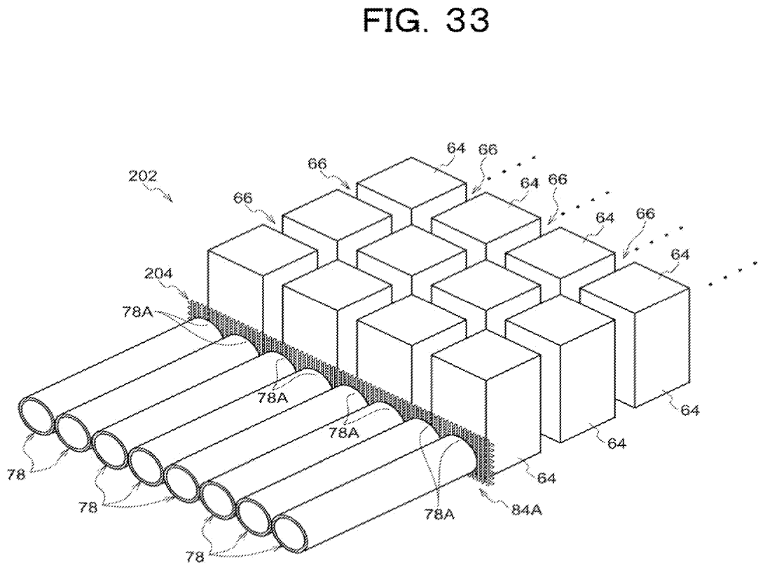

In a third modification illustrated in FIG. 33, as an example of the gap portion, a net member 204 separate from the transport pipe 78 and the evaporation unit 62 is provided. The net member 204 is arranged between the transport pipe 78 and the evaporation unit 62, with one surface in contact with the transport pipe 78 and the other surface in contact with the evaporation unit 62. Note that, in the third modification, the inclined portion 82A of the first embodiment (see FIG. 9) is not formed at the one end portion 78A of the transport pipe 78, and the one end portion 78A is orthogonal to the longitudinal direction of the transport pipe 78.

The net member 204 is a member capable of moving fluid in the thickness direction (arrow T direction), and the net member 204 forms the gap 84A between the transport pipe 78 and the evaporation unit 62. Thus, the one end portion 78A of the transport pipe 78 is not blocked by the evaporation unit 62, and the flow path of the refrigerant RF from the one end portion 78A toward the evaporation unit 62 is secured. For example, also in the structure illustrated in FIG. 14, the structure is achieved that facilitates movement of the refrigerant RF in the liquid phase from the transport pipe 78 to the evaporation unit 62.

In the third modification illustrated in FIG. 33, the net member 204 as an example of the gap portion is separate from the transport pipe 78 and the evaporation unit 62. Thus, the net member 204 does not affect the shape of the transport pipe 78 or the evaporation unit 62. For example, it is not needed to process the one end portion 78A of the transport pipe 78, and the structure may be simplified.

The net member 204 is arranged between the transport pipe 78 and the evaporation unit 62, and is in contact with both of them. With this configuration, a relative position between the transport pipe 78 and the evaporation unit 62 is maintained, so that the state where the gap 84A is formed may also be maintained.

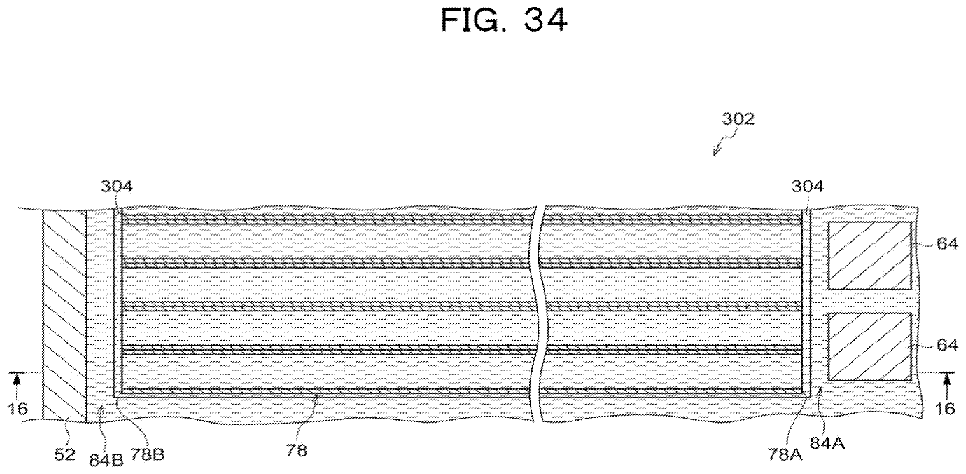

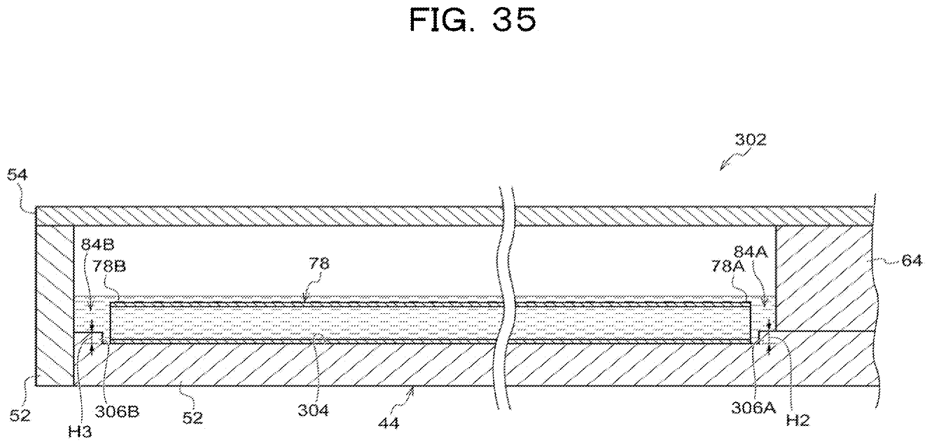

Furthermore, as the structure in which a gap is provided between the transport pipe 78 and the evaporation unit 62, a fourth modification illustrated in FIGS. 34 and 35 may be applied.

In the fourth modification, the bottom plate 52 is provided with a recess 304. The recess 304 has a shape capable of accommodating a lower portion of each transport pipe 78. In addition, as a part of the bottom plate 52, a wall portion 306A is provided between the recess 304 and the evaporation unit 62. Furthermore, as a part of the bottom plate 52, a second wall portion 306B is provided between the recess 304 and the side wall 44S of the container 44. Substantially, the wall portion 306A and the second wall portion 306B are portions of the bottom plate 52 where the recess 304 is not provided.

The wall portion 306A faces the one end portion 78A of the transport pipe 78, and is set to a height H2 that does not obstruct a substantial flow of the refrigerant RF in an inner peripheral portion of the transport pipe 78. In addition, the wall portion 306A forms the gap 84A between the one end portion 78A of the transport pipe 78 and the condensation unit 72.

In the fourth modification, the wall portion 306A forms the gap 84A between the transport pipe 78 and the evaporation unit 62. Thus, the one end portion 78A of the transport pipe 78 is not blocked by the evaporation unit 62, and the flow path of the refrigerant RF from the one end portion 78A toward the evaporation unit 62 is secured. For example, also in the fourth modification, the structure is achieved that facilitates movement of the refrigerant RF in the liquid phase from the transport pipe 78 to the evaporation unit 62.

The second wall portion 306B faces the another end portion 78B of the transport pipe, and is set to a height H3 that does not obstruct the substantial flow of the refrigerant RF in the inner peripheral portion of the transport pipe 78. In addition, the second wall portion 306B forms the second gap 84B between the another end portion 78B of the transport pipe 78 and the side wall 44S of the container 44. For example, in the third embodiment, the second wall portion 306B is an example of the second gap portion. Note that, since the height H2 of the wall portion 306A and the height H3 of the second wall portion 306B both correspond to the depth in the recess 304, the height H2 of the wall portion 306A and the height H3 of the second wall portion 306B are equal to each other.

In the fourth modification, the wall portion 306A as an example of the gap portion is provided in the container 44. Since the gap portion is not provided in the transport pipe 78, it is not needed to process the one end portion 78A of the transport pipe 78, and the structure may be simplified. Furthermore, since it is not needed to provide a new member as the gap portion, the number of parts does not increase.

In the fourth modification, the container 44 is provided with the recess 304. As a portion of the transport pipe 78 facing the one end portion 78A, a structure having the gap portion may be achieved with a simple structure.

Furthermore, since the transport pipe 78 is accommodated in the recess 304 of the bottom plate 52, a space between the transport pipe 78 and the top plate 54 may be secured wider as compared with a structure without the recess 304.

In the above, in the evaporation unit 62, the column member 64 is mentioned as a member for forming the groove 66, but the member forming the groove 66 is not limited to the column member. For example, a structure may be adopted in which a plurality of wall members extending in the depth direction is arranged side by side at regular intervals in the width direction. In the structure having the wall members, a groove extending in the depth direction is formed between the wall members.

In each of the embodiments described above, the columns 56 are arranged between the top plate 54 and the bottom plate 52 inside the container 44. Since the interval between the top plate 54 and the bottom plate 52 may be maintained by the columns 56, it is possible to secure a volume inside the container 44 for circulating the refrigerant RF while making the phase transition between the liquid phase and the gas phase. For example, the inside of the container 44 is maintained at a low pressure compared to an atmospheric pressure in order to promote vaporization of the refrigerant RF in the liquid phase. In this case, a force in an approaching direction acts on the top plate 54 and the bottom plate 52 due to the pressure difference between a pressure inside the container 44 (vapor pressure of the refrigerant RF in the gas phase) and the atmospheric pressure. Even when such a force acts, the interval between the top plate 54 and the bottom plate 52 may be maintained.

Note that the columns 56 may be provided on the top plate 54 and have a structure in which lower ends contact the bottom plate 52, or may be separate from both the top plate 54 and the bottom plate 52 and have a structure in which upper ends contact the top plate 54 and the lower ends contact the bottom plate 52.

The transport pipes 78 are fixed to the container 44 by the fixture 86. The transport pipes 78 are not fixed to the container by so-called brazing or adhesion, and no solder or adhesive is needed. Then, since the solder or the adhesive does not melt out due to a temperature change (high temperature) or the like accompanying the use of the cooling device 42, there is no effect on the phase transition of the refrigerant RF inside the container 44.

Furthermore, since the plurality of transport pipes 78 is fixed in contact with the bottom plate 52 by the fixture 86, a sufficient flow path cross-sectional area may be secured between the top plate 54 and the transport pipe 78 for substantially moving the refrigerant RF in the gas phase.

The top plate 54 is provided with the protrusions 76. The refrigerant RF in the gas phase that flows while contacting the top plate 54 is condensed and liquefied by heat radiation to the outside of the container 44 through the top plate 54. At this time, as illustrated in FIG. 12, the protrusions 76 increase a substantial contact area in which the refrigerant RF contacts the top plate 54 as compared with a structure without the protrusions 76. With this configuration, the refrigerant RF in the gas phase is easily liquefied as droplets RD, and liquefaction of the refrigerant RF may be promoted. In addition, since the liquefied refrigerant RF is efficiently dropped along the protrusions 76, a liquid film may be maintained thin at a portion of the top plate 54 where the protrusions 76 are not formed. By maintaining the liquid film thin, a structure may be achieved in which heat transfer from the refrigerant RF in the gas phase to the top plate 54 is efficiently performed, and a high condensation and liquefaction capacity of the refrigerant RF is maintained.

The container 44 is provided with the fastening holes 88. By inserting the fasteners into the fastening holes 88, it is possible to easily achieve a structure in which the cooling device 42 is fixed to the substrate 34, and further fixed to the element 36 to be cooled.

The container 44 has the injection hole 92. Through the injection hole 92, the refrigerant RF may be easily injected into the inside of the container 44 through the injection pipe 96. Then, by filling the injection pipe 96 with the plug 94, a structure may be achieved in which the injection hole 92 is sealed with the plug 94, and the refrigerant RF is sealed inside the container 44.

In the technology of the present disclosure, the container 44, the evaporation unit 62, the condensation unit 72, the movement region 74, and the transport pipes 78 are not limited as long as they satisfy thermal conductivity, heat resistance, pressure resistance, and the like needed for the cooling device, and may be made of metal. For example, when they are made of copper, they may exhibit high thermal conductivity. As a flow path member, a resin (silicone resin or the like) may be used other than metal.

By brazing, fusing, or adhering these members, for example, strength and airtightness of the container 44 may be secured high.

While the embodiments of the technology disclosed in the present application have been described thus far, the technology disclosed in the present application is not limited to the embodiments described above and it will be understood that, in addition to the embodiments described above, various modifications may be made and implemented within the spirit and scope of the technology.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A cooling device comprising:
a downstream heat radiation member that includes a plurality of downstream fins; and
an upstream heat radiation member that is arranged on an upstream side in a flow direction of cooling air with a gap from the downstream heat radiation member, includes a plurality of upstream fins, and is provided with a low pressure loss portion in which pressure loss is lower than pressure loss in another portion in one portion in a fin arrangement direction orthogonal to the flow direction.

2. The cooling device according to claim 1, wherein the low pressure loss portion is provided at a central portion of the upstream fins in the fin arrangement direction.

3. The cooling device according to claim 2, wherein downstream ends of the plurality of upstream fins gradually approach the downstream heat radiation member toward the central portion.

4. The cooling device according to claim 2, further comprising a wide portion which is provided on the upstream heat radiation member and in which a width of the upstream heat radiation member in the fin arrangement direction is wider than a width of the downstream heat radiation member.

5. The cooling device according to claim 2, wherein a center line of the upstream heat radiation member is at the same position as the center line of the downstream heat radiation member in the fin arrangement direction.

6. The cooling device according to claim 2, further comprising an inclined plate that is inclined from the upstream side toward a downstream side to a side of the central portion between the upstream heat radiation member and the downstream heat radiation member.

7. The cooling device according to claim 1, wherein
the upstream heat radiation member includes an upstream support plate that supports the upstream fins, and
the upstream support plate is provided with a penetration portion that penetrates the upstream support plate in the flow direction.

8. The cooling device according to claim 1, wherein a part or whole of the downstream fins and the upstream fins is provided with surface irregularities.

9. The cooling device according to claim 1, wherein a part or whole of the downstream fins and the upstream fins is provided with a through hole that penetrates in a plate thickness direction.

10. The cooling device according to claim 1, wherein, in the low pressure loss portion, pressure loss is reduced by making arrangement density of the upstream fins in the one portion lower than the arrangement density of the upstream fins in the another portion.

11. The cooling device according to claim 1, wherein the pressure loss intermittently changes between the low pressure loss portion and a high pressure loss portion in which the pressure loss is high.

12. The cooling device according to claim 1, wherein the pressure loss continuously changes between the low pressure loss portion and a high pressure loss portion in which the pressure loss is high.

13. The cooling device according to claim 1, further comprising a heat transfer member to which the upstream fins and the downstream fins are attached, and which transfers heat between the upstream fins and the downstream fins.

14. The cooling device according to claim 13, wherein, in the heat transfer member, a refrigerant is sealed such that the refrigerant is movable between an attachment portion of the upstream fins and an attachment portion of the downstream fins.

15. The cooling device according to claim 14, further comprising:
an evaporation portion that evaporates, inside the heat transfer member, the refrigerant in a liquid phase by receiving heat;
a condensation portion that condenses, inside the heat transfer member, the refrigerant in a gas phase by heat radiation;
a transport portion that transports, inside the heat transfer member, the refrigerant in the liquid phase to the evaporation portion by surface tension; and
a gap portion that generates a gap between the transport portion and the evaporation portion, in which the refrigerant in the liquid phase moves from the transport portion to the evaporation portion.
